(19) United States
(12) Patent Application Publication
(10) Pub. No.: US 2015/0160308 A1
(43) Pub. Date: Jun. 11, 2015

(54) ORTHOGONAL FLUXGATE SENSOR

(71) Applicant: SAMSUNG ELECTRO-MECHANICS CO., LTD., Suwon-Si (KR)

(72) Inventors: Dae Ho KIM, Suwon-Si (KR); Eun Tae PARK, Suwon-Si (KR)

(73) Assignee: SAMSUNG ELECTRO-MECHANICS CO., LTD., Suwon-Si (KR)

(21) Appl. No.: 14/218,480

(22) Filed: Mar. 18, 2014

(30) Foreign Application Priority Data
Dec. 9, 2013 (KR) 10-2013-0152365

(51) Int. Cl. G01R 33/04; G01R 33/00

(52) U.S. Cl. CPC G01R 33/04; G01R 33/0005

(57) ABSTRACT

There is provided an orthogonal fluxgate sensor including: a magnetic core having a flat plate shape; and first and second coils enclosing the magnetic core in a solenoid form, wherein the first and second coils are disposed to be orthogonal to one another, and when alternating current (AC) is applied to the first coil, an AC voltmeter is connected to the second coil, and when AC is applied to the second coil, the AC voltmeter is connected to the first coil.

### CROSS-REFERENCE TO RELATED APPLICATION

This application claims the benefit of Korean Patent Application No. 10-2013-0152365 filed on Dec. 9, 2013, with the Korean Intellectual Property Office, the disclosure of which is incorporated herein by reference.

### BACKGROUND

The present disclosure relates to an orthogonal fluxgate sensor.

A fluxgate sensor is a type of magnetic field sensor measuring a magnitude of a relatively weak external magnetic field by utilizing large permeability of a ferromagnetic material that is easily saturated in a magnetic field.

A fluxgate sensor has been extensively utilized as a sensor for precisely measuring a geo-magnetic field in spaceship and artificial satellites to measure a magnetic field in celestial bodies and space.

In addition, a fluxgate sensor may also be used as an electronic compass of portable electronic devices such as a smartphone, a navigation device, and the like.

An electronic compass of portable electronic devices senses a geo-magnetic field and provides information regarding a direction of a smartphone, a navigation device, and the like, providing a method of overcoming shortcomings of a global positioning system (GPS)-based location tracking.

Currently, a magnetoresistive (MR) sensor, a magnetoimage (MI) sensor, a resonator sensor based on Lorentz force, and a hall sensor, implementing low-cost production and low-power driving, while satisfying demand for precision and resolution, are typical geomagnetic sensors applied to electronic compasses of most portable electronic devices.

Current development of such sensors are directed toward improvement of more precise resolution and effective initialization performance to meet new demand for augmented reality, game controllers, indoor navigation devices, and the like, in line with the development of increasingly diversified applications.

A fluxgate sensor supports excellent resolution and effective initialization performance, and thus, if such a fluxgate sensor is miniaturized and driven with low power, it may be widely utilized in portable electronic devices, and the like.

### SUMMARY

An aspect of the present disclosure may provide an orthogonal fluxgate sensor utilizing a magnetic core and two coil structures perpendicular to one another.

An aspect of the present disclosure may also provide an orthogonal fluxgate sensor including a magnetic core and two coil structures perpendicular to one another applied to printed circuit board (PCB) or a semiconductor wafer.

An aspect of the present disclosure may also provide a compact orthogonal fluxgate sensor having a simple structure in which two coils perpendicular to one another alternately serve as a magnetic field generating coil and a detecting coil.

According to a first aspect of the present disclosure, an orthogonal fluxgate sensor may include: a magnetic core having a flat plate shape; and first and second coils enclosing the magnetic core in a solenoid form, wherein the first and second coils are disposed to be orthogonal to one another, and when an alternating current (AC) power source is connected to the first coil, an AC voltmeter is connected to the second coil, and when the AC power source is connected to the second coil, the AC voltmeter is connected to the first coil.

A planar shape of the magnetic core may be any one of square, rectangular, circular, and oval shapes.

The magnetic core may have lower demagnetizing field over a magnetic field whose direction is parallel to the plane thereof than those over a magnetic field whose direction is perpendicular to the plane.

According to a second aspect of the present disclosure, an orthogonal fluxgate sensor may include: a magnetic core having a flat plate shape; a first coil disposed above the magnetic core and having a spiral shape with the parts of the first coil directly above the magnetic core forming parallel lines; and a second coil disposed below the magnetic core and having a spiral shape with the parts of the second coil directly below the magnetic core forming parallel lines, wherein the first and second coils are disposed to be orthogonal to one another, and when an alternating current (AC) power source is connected to the first coil, an AC voltmeter is connected to the second coil, and when the AC power source is connected to the second coil, the AC voltmeter is connected to the first coil.

A planar shape of the magnetic core may be any one of square, rectangular, circular, and oval shapes.

The magnetic core may have lower demagnetizing field over a magnetic field whose direction is parallel to the plane thereof than those over a magnetic field whose direction is perpendicular to the plane.

The magnetic core may be positioned within a region of the first coil in which a current flows in one direction and within a region of the second coil in which a current flows in another direction.

According to a third aspect of the present disclosure, an orthogonal fluxgate sensor may include: a first substrate having a magnetic core formed therein; second and third substrates stacked above and below the first substrate and having a first coil formed to enclose the magnetic core in a solenoid form; and fourth and fifth substrates stacked above the second substrate and below the third substrate and having a second coil enclosing the magnetic core in a solenoid form, wherein the first and second coils are disposed to be orthogonal to one another, and when an alternating current (AC) power source is connected to the first coil, an AC voltmeter is connected to the second coil, and when the AC power source is connected to the second coil, the AC voltmeter is connected to the first coil.

The magnetic core may have a flat plate shape.

The magnetic core may have lower demagnetizing field over a magnetic field whose direction is parallel to the plane thereof than those over a magnetic field whose direction is perpendicular to the plane thereof.

A planar shape of the magnetic core may be any one of square, rectangular, circular, and oval shapes.

The second and third substrates may have conductive patterns formed therein, and the first through third substrates have first via holes to allow end portions of the respective conductive patterns to be connected therethrough to form the first coil in a solenoid form.

The fourth and fifth substrates may have conductive patterns formed therein, and the first through third substrates may have second via holes to allow end portions of the respective conductive patterns to be connected therethrough to form the second coil in a solenoid form.

The fourth or fifth substrate may have an electrode pattern to apply a current to the first or second coil.

According to a fourth aspect of the present disclosure, an orthogonal fluxgate sensor may include: a first substrate having a magnetic core formed therein; a second substrate staked above the first substrate and having a first coil patterned to have a spiral shape with the parts of the coil directly above the magnetic core forming parallel lines; and a third substrate stacked below the first substrate and having a second coil patterned to have a spiral shape with the parts of the coil directly below the magnetic core forming parallel lines, wherein the first and second coils are patterned in the second and third substrates such that they are perpendicular to one another, and when an alternating current (AC) power source is connected to the first coil, an AC voltmeter is connected to the second coil, and when the AC power source is connected to the second coil, the AC voltmeter is connected to the first coil.

The magnetic core may have a flat plate shape.

The magnetic core may have lower demagnetizing field over a magnetic field whose direction is parallel to the plane than those over a magnetic field whose direction is perpendicular to the plane.

A planar shape of the magnetic core may be any one of square, rectangular, circular, and oval shapes.

The magnetic core may be positioned within a region of the first coil in which a current flows in one direction and within a region of the second coil in which a current flows in another direction.

The magnetic core may be positioned between start points and end points of the first and second coils patterned to have a spiral shape.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating an orthogonal fluxgate sensor according to a first exemplary embodiment of the present disclosure;

FIG. 2 is a perspective view schematically illustrating an orthogonal fluxgate sensor according to a second exemplary embodiment of the present disclosure;

FIG. 3 is an exploded perspective view schematically illustrating an orthogonal fluxgate sensor according to a third exemplary embodiment of the present disclosure;

FIG. 4 is an exploded perspective view schematically illustrating an orthogonal fluxgate sensor according to a fourth exemplary embodiment of the present disclosure;

FIGS. 5A and 5B are plan views illustrating a position of a magnetic core in the orthogonal fluxgate sensor according to the fourth exemplary embodiment of the present disclosure; and

FIGS. 6A through 6D are perspective views illustrating a modified example of a magnetic core.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

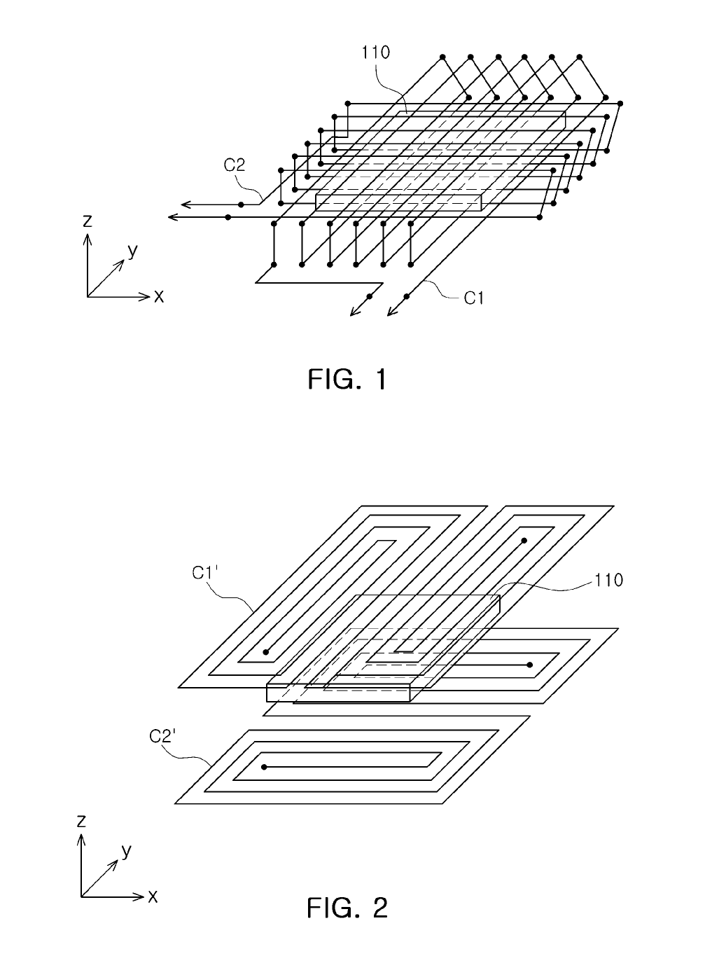

FIG. 1 is a perspective view schematically illustrating an orthogonal fluxgate sensor according to a first exemplary embodiment of the present disclosure.

Referring to FIG. 1, an orthogonal fluxgate sensor according to the first exemplary embodiment of the present disclosure may include a magnetic core 110 and first and second coils C1 and C2 enclosing the magnetic core 110 in a solenoid form.

The magnetic core 110 may have a flat plate shape, and a plane shape of the magnetic core 110 may be any one of square, rectangular, circular, and oval shapes.

The magnetic core 110 may be a soft magnet having small residual magnetization and high permeability, and may be formed of spinel-type ferrite, an amorphous alloy, and the like.

The magnetic core 110 may be magnetized when an external magnetic field is applied thereto, and may be demagnetized when the applied external magnetic field is removed.

The magnetic core 110 may be formed to be thin in a thickness direction (z-axis direction) thereof, relative to a horizontal length (length in x-axis direction) and a horizontal length (length in y-axis direction) thereof.

Thus, the magnetic core 110 may have lower demagnetizing field over a magnetic field whose direction is parallel to the plane thereof (x- or y-axis direction) than those over a magnetic field whose direction is perpendicular to the plane thereof (z-axis direction).

The magnetic core 110 may be readily magnetized by the magnetic field in the x-axis direction induced by the first coil C1 or the magnetic field in the y-axis direction induced by the second coil C2.

The first coil C1 and the second coil C2 may be provided to enclose the magnetic core 110 in a solenoid form, and may be disposed to be orthogonal to one another.

The first and second coils C1 and C2 may be magnetic field generating coils generating a magnetic field to magnetize the magnetic core 110 upon receiving an alternating current (AC) current applied thereto, or may be detecting coils measuring an induction voltage due to a change in magnetic moment of the magnetic core 110 caused by an external magnetic field.

Namely, in the orthogonal fluxgate sensor according to the first exemplary embodiment, when at least one of the first and second coils C1 and C2 serves as a magnetic field generating coil, the other may serve as a detecting coil.

To this end, in a case in which an AC power source is connected to the first coil C1, an AC voltmeter may be connected to the second coil C2, and in a case in which the AC power source is connected to the second coil C2, the AC voltmeter may be connected to the first coil C1.

Thus, the first and second coils C1 and C2 may alternately serve to generate a magnetic field and detect a change in magnetic flux.

For example, in a case in which AC is applied to the first coil C1 to generate a magnetic field, an AC voltage induced to the second coil C2 due to a change in magnetic moment of the magnetic core 110 may be measured, and in a case in which AC is applied to the second coil C2 to generate a magnetic field, an AC voltage induced to the first coil C1 due to a change in magnetic moment of the magnetic core 110 may be measured.

The orthogonal fluxgate sensor according to the first exemplary embodiment of the present disclosure may operate as follows.

A method of measuring an external magnetic field (geo-magnetic field) in the x-axis direction will be described with reference to FIG. 1.

When an external magnetic field in the x-axis direction is applied, the magnetic core 110 has magnetic moment proportional to the external magnetic field in the x-axis direction.

Here, a current is applied to the second coil C2 to apply a magnetic field in the y-axis direction to the magnetic core 110.

Namely, in the orthogonal fluxgate sensor according to the first exemplary embodiment of the present disclosure, the direction (here, the x-axis direction) of the external magnetic field intended to be measured and the direction (here, the y-axis direction) of the magnetic field generated by the magnetic field generating coil (here, the second coil C2) to magnetize the magnetic core 110 form a right angle.

The current applied to the second coil C2 is AC, so the direction of the magnetic field thereof is repeatedly changing between a positive (+) direction and a negative (−) direction of the y axis.

When an instantaneous current value of the AC applied to the second coil C2 is 0, the magnetic moment of the magnetic core 110 is maintained at the original value (with its component only along x-axis).

When the instantaneous current value of the AC applied to the second coil C2 has a maximum positive value, the magnetic moment of the magnetic core 110 is saturated to the y-axis direction, and thus, the original component along the x-axis is rapidly reduced.

Here, the component along the x-axis of the magnetic moment of the magnetic core 110 is changed, and a change in magnetic flux corresponding thereto may be sensed by the first coil C1.

Each time the instantaneous current value of the AC applied to the second coil C2 is changing between 0 and the maximum value thereof, the magnetic moment of the magnetic core 110 in the x-axis direction is changed and may be measured by the voltage induced to the first coil C1.

The measured voltage of the first coil C1 is proportional to a magnitude of the external magnetic field in the x-axis direction.

Namely, the external magnetic field in the x-axis direction may be detected by measuring the voltage induced to the first coil C1.

Here, the second coil C2 to which the AC power source is connected may serve as a magnetic field generating coil, and the first coil C1 connected to the AC voltmeter may serve as a detecting coil.

Hereinafter, a method of measuring an external magnetic field (geo-magnetic field) in the y-axis direction will be described.

When an external magnetic field in the y-axis direction is applied, the magnetic core 110 has magnetic moment proportional to the external magnetic field in the y-axis direction.

Here, a current is applied to the first coil C1 to apply a magnetic field in the x-axis direction to the magnetic core 110.

Namely, in the orthogonal fluxgate sensor according to the first exemplary embodiment of the present disclosure, the direction (here, the y-axis direction) of the external magnetic field intended to be measured and the direction (here, the x-axis direction) of the magnetic field generated by the magnetic field generating coil (here, the first coil C1) to magnetize the magnetic core 110 form a right angle.

The current applied to the first coil C1 is AC, so the direction of the magnetic field thereof is repeatedly changing between a positive (+) direction and a negative (−) direction of the x axis.

When an instantaneous current value of the AC applied to the first coil C1 is 0, the magnetic moment of the magnetic core 110 is maintained at the original value (with its component only along y-axis).

When the instantaneous current value of the AC applied to the first coil C1 has a maximum positive value, the magnetic moment of the magnetic core 110 is saturated in the x-axis direction, and thus, the original component along the y-axis is rapidly reduced.

Here, the component along the y-axis of the magnetic moment of the magnetic core 110 is changed, and a change in magnetic flux corresponding thereto may be sensed by the second coil C2.

Each time the instantaneous current value of the AC applied to the first coil C1 is changing between 0 and the maximum value thereof, the magnetic moment of the magnetic core 110 in the y-axis direction is changed and may be measured by the voltage induced to the second coil C2.

The measured voltage of the second coil C2 is proportional to a magnitude of the external magnetic field in the y-axis direction.

Namely, the external magnetic field in the y-axis direction may be detected by measuring the voltage induced to the second coil C2.

Here, the first coil C1 to which the AC power source is connected may serve as a magnetic field generating coil, and the second coil C2 connected to the AC voltmeter may serve as a detecting coil.

In the orthogonal fluxgate sensor according to the first exemplary embodiment of the present disclosure, since the first and second coils C1 and C2 alternately serve as a magnetic field generating coil and a detecting coil, eliminating the need for a separate magnetic field generating coil and a detecting coil, the overall volume of the sensor may be reduced.

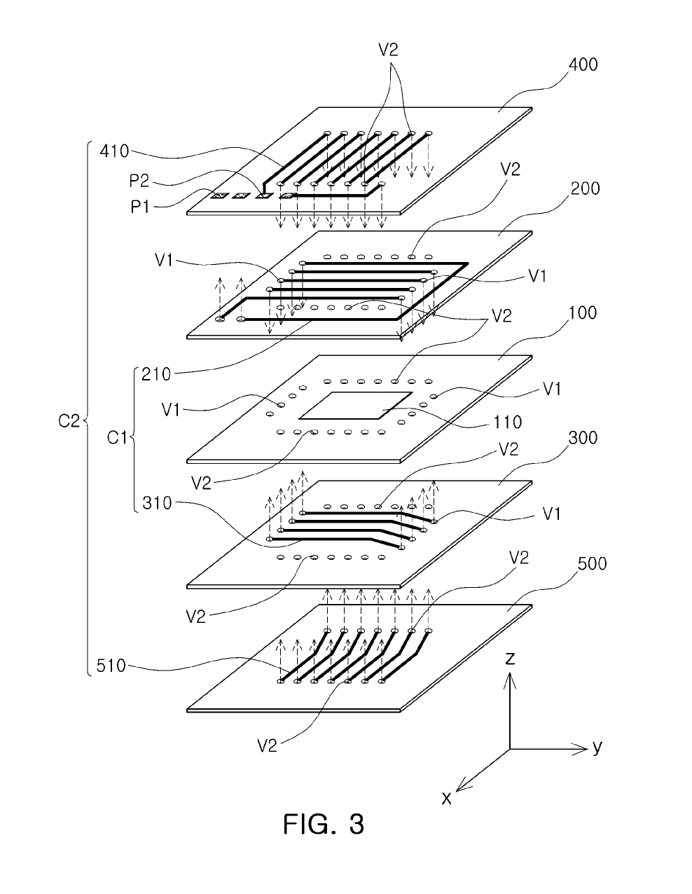

FIG. 2 is a perspective view schematically illustrating an orthogonal fluxgate sensor according to a second exemplary embodiment of the present disclosure.

Referring to FIG. 2, the orthogonal fluxgate sensor according to the second exemplary embodiment of the present disclosure is identical to the orthogonal fluxgate sensor according to the first exemplary embodiment of the present disclosure as described above, except for first and second coils C1′ and C2′. Thus, descriptions thereof, excluding those of the first and second coils C1′ and C2′, will be omitted.

The first coil C1′ may be disposed above the magnetic core 110, and the second coil C2′ may be disposed below the magnetic core 110.

The first and second coils C1′ and C2′ may have a spiral shape with the parts of the first and second coils C1′ and C2′ directly above or below the magnetic core 110 forming parallel lines, and may be disposed to be orthogonal to one another.

The first coil C1′ may be formed by connecting the outermost coil strands of two coils wound in the same direction.

Also, the first coil C1′ may be formed to spread, while being wound in one direction, and be rewound in the opposite direction.

In other words, the first coil C1′ may have a dual-spiral structure.

Thus, when it is assumed that a current flows from a start point S to an end point E of the first coil C1′, in an inner portion of the first coil C1′, the current flows in the same direction.

The shape of the second coil C2′ may be identical to that of the first coil C1′, and the first and second coils C1′ and C2′ may be disposed to perpendicular to one another.

Here, the magnetic core 110 may be positioned within the region of the first coil C1′ in which the current flows in one direction and the region of the second coil C2′ in which the current flows in another direction.

Also, the magnetic core 110 may be positioned between the start points S and the end points E of the first and second coils C1′ and C2′.

Thus, a magnetic field may be applied to the entirety of the magnetic core 110 in a predetermined direction by the first and second coils C1′ and C2′.

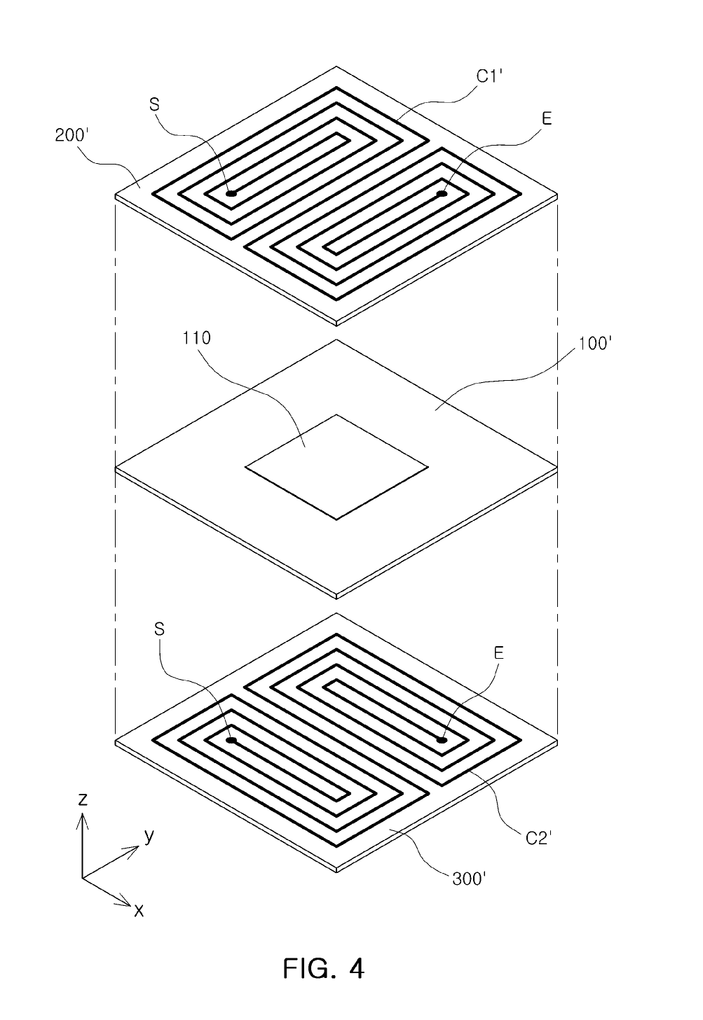

FIG. 3 is an exploded perspective view schematically illustrating an orthogonal fluxgate sensor according to a third exemplary embodiment of the present disclosure.

Referring to FIG. 3, the orthogonal fluxgate sensor according to the third exemplary embodiment of the present disclosure may include a first substrate 100 in which a magnetic core 110 is formed, and second, third, fourth, and fifth substrates 200, 300, 400, and 500 in which conductive patterns 210, 310, 410, and 510 are formed, respectively.

The second to fifth substrates 200 to 500 may be respectively stacked above and below the first substrate 100 with the first substrate 100 as a center, forming a multi-layer substrate.

The magnetic core 110 may be formed in the first substrate 100. The magnetic core 110 may be formed by depositing a magnetic thin film on the first substrate 100 by utilizing a thin film deposition method such as physical vapor deposition, chemical deposition, electro-deposition, or the like.

The magnetic core 110 may have a flat, thin plate shape, and thus, the magnetic core 110 may be a soft magnet having small residual magnetization and high permeability, and may be made of spinel-type ferrite, an amorphous alloy, and the like.

The magnetic core 110 may be magnetized when an external magnetic field is applied thereto, and demagnetized when the applied external magnetic field is removed.

The magnetic core 110 may be formed to be thin in the thickness direction (z-axis direction) thereof, relative to the horizontal lengths (lengths in x-axis or y-axis directions) thereof.

Thus, the magnetic core 110 may have lower demagnetizing field over the magnetic field whose direction (x- or y-axis directions) is parallel to the plane thereof than those over the magnetic field whose direction (z-axis direction) is perpendicular to the plane thereof.

The magnetic core 110 may be readily magnetized by the magnetic field in the x-axis direction induced by the first coil C1 and the magnetic field in the y-axis direction induced by the second coil C2.

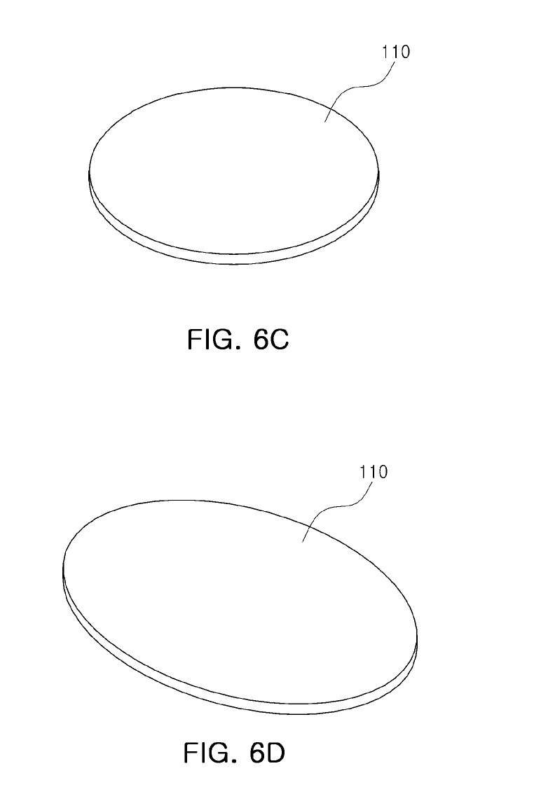

Meanwhile, the planar shape of the magnetic core 110 may be any one of a square, rectangular, circular, and oval shapes as illustrated in FIGS. 6A through 6D.

The second substrate 200 may be stacked on the first substrate 100 and the third substrate 300 may be stacked below the first substrate 100.

Conductive patterns 210 and 310 may be formed in the second and third substrates 200 and 300, and each of the conductive patterns 210 and 310 may be electrically connected by first via holes V1 formed in the first to third substrate 100 to 300.

End portions of the conductive patterns 210 and 310 formed in the second and third substrates 200 and 300, may be connected by the first via holes V1 to enclose the magnetic core 110 in a solenoid form.

For example, the conductive patterns 210 and 310 formed in the second and third substrates 200 and 300, may be connected by the first via holes V1 to configure the first coil C1 enclosing the magnetic core 110 in a solenoid form.

The fourth substrate 400 may be stacked on the second substrate 200, and the fifth substrate 500 may be stacked below the third substrate 300.

Conductive patterns 410 and 510 may be formed on the fourth and fifth substrates 400 and 500, and each of the conductive patterns 410 and 510 may be electrically connected by second via holes V2 formed in the first to fifth substrates 100 to 500.

End portions of the conductive patterns 410 and 510 formed in the fourth and fifth substrates 400 and 500, may be connected by the second via holes V2 to enclose the magnetic core 110 in a solenoid form.

For example, the conductive patterns 410 and 510 formed in the fourth and fifth substrates 400 and 500, may be connected by the second via holes V2 to configure the second coil C2 enclosing the magnetic core 110 in a solenoid form.

Here, the first and second coils C1 and C2 may be disposed to perpendicular to one another.

The first and second coils C1 and C2 may be magnetic field generating coils generating a magnetic field to magnetize the magnetic core 110 upon receiving an alternating current (AC) applied thereto, or may be detecting coils measuring an induction voltage according to a change in magnetic moment of the magnetic core 110 caused by an external magnetic field.

Namely, in the orthogonal fluxgate sensor according to the third exemplary embodiment, when at least one of the first and second coils C1 and C2 serves as a magnetic field generating coil, the other may serve as a detecting coil.

To this end, in a case in which an AC power source is connected to the first coil C1, an AC voltmeter may be connected to the second coil C2, and in a case in which an AC power source is applied to the second coil C2, the AC voltmeter may be connected to the first coil C1.

Thus, the first and second coils C1 and C2 may alternately serve to generate a magnetic field and detect a change in magnetic flux.

For example, in a case in which AC is applied to the first coil C1 to generate a magnetic field, a voltage induced to the second coil C2 due to a change in magnetic moment of the magnetic core 110 may be measured, and in a case in which AC is applied to the second coil C2 to generate a magnetic field, a voltage induced to the first coil C1 due to a change in magnetic moment of the magnetic core 110 may be measured.

Electrode patterns P1 and P2 may be disposed on the fourth or fifth substrate 400 or 500 to apply a current to the first or second coil C1 or C2.

The orthogonal fluxgate sensor according to the third exemplary embodiment of the present disclosure may operate as follows.

A method of measuring an external magnetic field (geo-magnetic field) in the z-axis direction will be described with reference to FIG. 3.

When an external magnetic field in the x-axis direction is applied, the magnetic core 110 has magnetic moment proportional to the external magnetic field in the x-axis direction.

Here, a current is applied to the second coil C2 to apply a magnetic field in the y-axis direction to the magnetic core 110.

Namely, in the orthogonal fluxgate sensor according to the third exemplary embodiment of the present disclosure, the direction (here, the x-axis direction) of the external magnetic field intended to be measured and the direction (here, the y-axis direction) of the magnetic field generated by the magnetic field generating coil (here, the second coil C2) to magnetize the magnetic core 110 form a right angle.

The current applied to the second coil C2 is AC, so the direction of the magnetic field thereof is repeatedly changing between a positive (+) direction and a negative (−) direction of the y axis.

When an instantaneous current value of the AC applied to the second coil C2 is 0, the magnetic moment of the magnetic core 110 is maintained at the original value (with its component only along x-axis).

When the instantaneous current value of the AC applied to the second coil C2 has a maximum positive value, the magnetic moment of the magnetic core 110 is saturated to the y-axis direction, and thus, the original component along the x-axis is rapidly reduced.

Here, the component along the x-axis of the magnetic moment of the magnetic core 110 is changed, and a change in magnetic flux corresponding thereto may be sensed by the first coil C1.

Each time the instantaneous current value of the AC applied to the second coil C2 is changing between 0 and the maximum value thereof, the magnetic moment of the magnetic core 110 in the x-axis direction is changed and may be measured by the voltage induced to the first coil C1.

The measured voltage of the first coil C1 is proportional to a magnitude of the external magnetic field in the x-axis direction.

Namely, the external magnetic field in the x-axis direction may be detected by measuring the voltage induced to the first coil C1.

Here, the second coil C2 to which the AC power source is connected may serve as a magnetic field generating coil, and the first coil C1 connected to the AC voltmeter may serve as a detecting coil.

Hereinafter, a method of measuring an external magnetic field (geo-magnetic field) in the y-axis direction will be described.

When an external magnetic field in the y-axis direction is applied, the magnetic core 110 has magnetic moment proportional to the external magnetic field in the y-axis direction.

Here, a current is applied to the first coil C1 to apply a magnetic field in the x-axis direction to the magnetic core 110.

Namely, in the orthogonal fluxgate sensor according to the third exemplary embodiment of the present disclosure, the direction (here, the y-axis direction) of the external magnetic field intended to be measured and the direction (here, the x-axis direction) of the magnetic field generated by the magnetic field generating coil (here, the first coil C1) to magnetize the magnetic core 110 form a right angle.

The current applied to the first coil C1 is AC, so the direction of the magnetic field thereof is repeatedly interchanged between a positive (+) direction and a negative (−) direction of the x axis.

When an instantaneous current value of the AC applied to the first coil C1 is 0, the magnetic moment of the magnetic core 110 is maintained at the original value (with its component only along y-axis).

When the instantaneous current value of the AC applied to the first coil C1 has a maximum positive value, the magnetic moment of the magnetic core 110 is saturated in the x-axis direction, and thus, the original component along the y-axis is rapidly reduced.

Here, the component along the y-axis of the magnetic moment of the magnetic core 110 is changed, and a change in magnetic flux corresponding thereto may be sensed by the second coil C2.

Each time the instantaneous current value of the AC applied to the first coil C1 is changing between 0 and the maximum value thereof, the magnetic moment of the magnetic core 110 in the y-axis direction is changed and may be measured by the voltage induced to the second coil C2.

The measured voltage of the second coil C2 is proportional to a magnitude of the external magnetic field in the y-axis direction.

Namely, the external magnetic field in the y-axis direction may be detected by measuring the voltage induced to the second coil C2.

Here, the first coil C1 to which the AC power source is connected may serve as a magnetic field generating coil, and the second coil C2 connected to the AC voltmeter may serve as a detecting coil.

In the orthogonal fluxgate sensor according to the third exemplary embodiment of the present disclosure, since the first and second coils C1 and C2 alternately serve as a magnetic field generating coil and a detecting coil, eliminating the need for a separate magnetic field generating coil and a detecting coil, the overall volume of the sensor may be reduced.

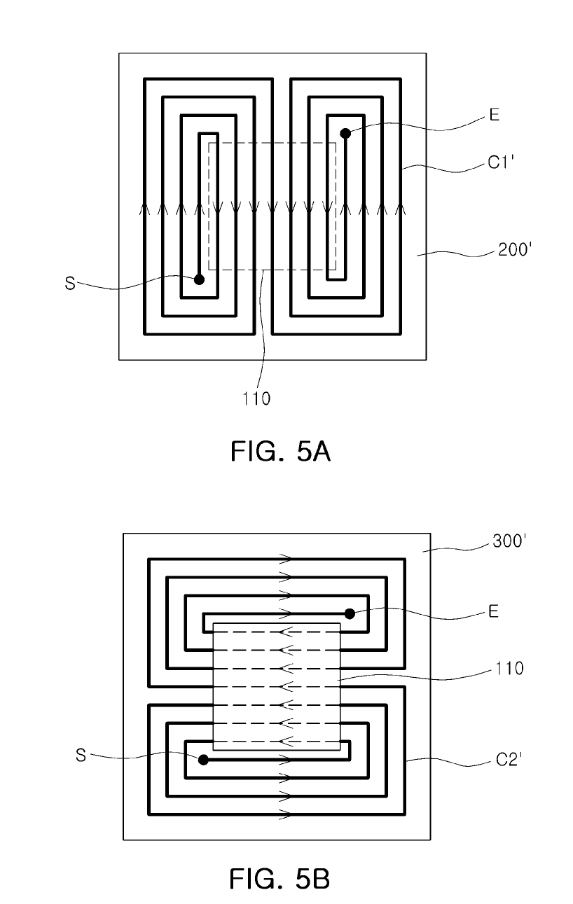

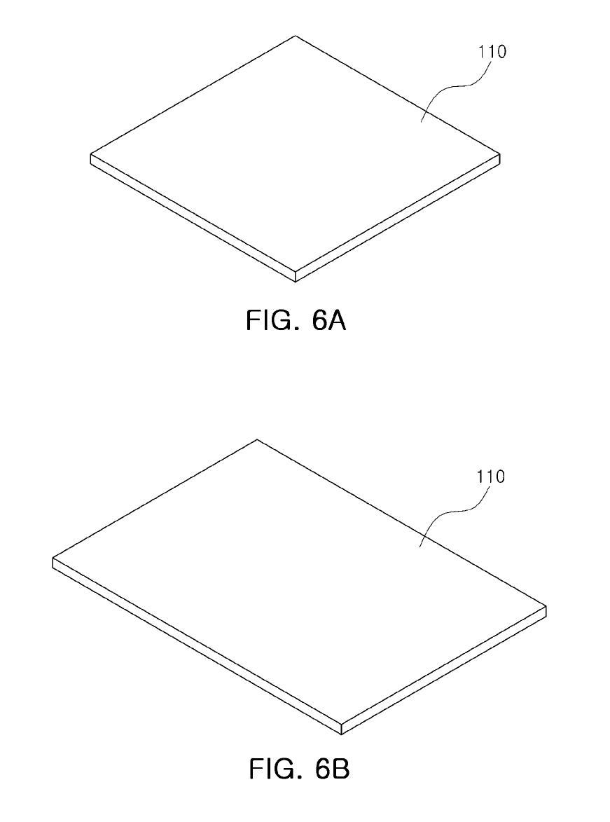

FIG. 4 is an exploded perspective view schematically illustrating an orthogonal fluxgate sensor according to a fourth exemplary embodiment of the present disclosure, and FIGS. 5A and 5B are plan views illustrating a position of a magnetic core in the orthogonal fluxgate sensor according to the fourth exemplary embodiment of the present disclosure.

Referring to FIGS. 4 through 5B, the orthogonal fluxgate sensor according to the fourth exemplary embodiment of the present disclosure may include a first substrate 100′, and second and third substrates 200′ and 300′ in which conductive patterns are formed.

The second and third substrates 200′ and 300′ may be stacked above and below the first substrate 100′ with the first substrate 100 as a center, forming a multi-layer substrate.

A magnetic core 110 may be formed in the first substrate 100′. The magnetic core 110 may be formed by depositing a magnetic thin film on the first substrate 100′ by utilizing a thin film deposition method such as physical vapor deposition, chemical deposition, electro-deposition, or the like.

The magnetic core 110 may be a soft magnet having small residual magnetization and high permeability, and may be made of spinel-type ferrite, an amorphous alloy, and the like.

The magnetic core 110 may be magnetized when an external magnetic field is applied thereto, and demagnetized when the applied external magnetic field is removed.

The magnetic core 110 may have a flat, thin plate shape, and thus, the magnetic core 110 may be formed to be thin in the thickness direction (z-axis direction) thereof, relative to the horizontal lengths (length in x- or y-axis directions) thereof.

Thus, the magnetic core 110 may have lower demagnetizing field over the magnetic field whose direction (x- or y-axis directions) is parallel to the plane thereof than those over the magnetic field whose direction (z-axis direction) is perpendicular to the plane thereof.

The magnetic core 110 may be readily magnetized by the magnetic field in the x-axis direction induced by the first coil C1′ and the magnetic field in the y-axis direction induced by the second coil C2′.

Meanwhile, the planar shape of the magnetic core 110 may be any one of a square, rectangular, circular, and oval shapes as illustrated in FIGS. 6A through 6D.

The second substrate 200′ may be stacked on the first substrate 100′ and the third substrate 300′ may be stacked below the first substrate 100′.

Conductive patterns may be formed in the second and third substrates 200′ and 300′.

For example, the first coil C1′ may be patterned to have a spiral shape in the second substrate 200′ such that the parts of the first coil C1′ directly above the magnetic core 110 form parallel lines, and the second coil C2′ may be patterned to have a spiral shape in the third substrate 300′ such that the parts of the second coil C2′ directly below the magnetic core 110 form parallel lines.

The first coil C1′ may be formed by connecting the outermost coil strands of two coils wound in the same direction.

Namely, the first coil C1′ may be formed to spread, while being wound in one direction, and be rewound in the opposite direction.

In other words, the first coil C1′ may have a dual-spiral structure.

The shape of the second coil C2′ may be identical to that of the first coil C1′, and the first and second coils C1′ and C2′ may be disposed to perpendicular to one another.

The first and second coils C1′ and C2′ may be spiral coils (magnetic field generating coils) generating a magnetic field to magnetize the magnetic core 110 upon receiving an alternating current (AC) applied thereto, or may be detecting coils measuring an induction voltage according to a change in magnetic moment of the magnetic core 110 caused by an external magnetic field.

Namely, in the orthogonal fluxgate sensor according to the fourth exemplary embodiment, when at least one of the first and second coils C1′ and C2′ serves as a magnetic field generating coil, the other may serve as a detecting coil.

To this end, in a case in which an AC power source is connected to the first coil C1′, an AC voltmeter may be connected to the second coil C2′, and in a case in which the AC power source is connected to the second coil C2′, the AC voltmeter may be connected to the first coil C1′.

Thus, the first and second coils C1′ and C2′ may alternately serve to generate a magnetic field and detect a change in magnetic flux.

For example, in a case in which AC is applied to the first coil C1′ to generate a magnetic field, a voltage induced to the second coil C2′ due to a change in magnetic moment of the magnetic core 110 may be measured, and in a case in which AC is applied to the second coil C2′ to generate a magnetic field, a voltage induced to the first coil C1′ due to a change in magnetic moment of the magnetic core 110 may be measured.

In the present exemplary embodiment, the magnetic core 110 is disposed between the first and second coils C1′ and C2′, but the present disclosure is not limited thereto and the magnetic core 110 may be positioned above or below the first and second coils C1′ and C2.

For example, the first substrate 100′ with the magnetic core 110 formed therein, the second substrate 200′ with the first coil C1′ formed therein, and the third substrate 300′ with the second coil C2′ formed therein may be stacked in order, or may be stacked in a reverse order.

This is because an operation or sensitivity of the sensor is not affected by stacking order as long as the magnetic core 110 is in proximity to the first and second coils C1′ and C2′.

Meanwhile, since the first coil C1′ may have a spiral shape, when a current is applied to the first coil C1′, the current flows in the same direction in the inner portion of the first coil C1′.

For example, referring to FIG. 5A, when it is assumed that a current flows from a start point S to an end point E of the first coil C1′ wound in a spiral shape, the current flows in the arrow direction illustrated in FIG. 5A, and in a portion (namely, an inner portion of the first coil C1′) between the start point Sand the endpoint E, the current flows in the same direction.

Also, referring to FIG. 5B, a current flows in the arrow direction illustrated in FIG. 5B in the second coil C2′, and in a portion (namely, an inner portion of the second coil C2′) between a start point S and an end point E of the second coil C2′, the current flows in the same direction.

Here, the magnetic core 110 may be positioned within the region of the first coil C1′ in which the current flows in one direction and the region of the second coil C2′ in which the current flows in another direction.

Also, the magnetic core 110 may be positioned between the start points S and the end points E of the first and second coils C1′ and C2′ patterned to have a spiral shape.

Thus, a magnetic field may be applied to the entirety of the magnetic core 110 in a predetermined direction by the first and second coils C1′ and C2′.

The orthogonal fluxgate sensor according to the fourth exemplary embodiment of the present disclosure may operate as follows.

A method of measuring an external magnetic field (geo-magnetic field) in the x-axis direction will be described with reference to FIG. 4.

When an external magnetic field in the x-axis direction is applied, the magnetic core 110 has magnetic moment proportional to the external magnetic field in the x-axis direction.

Here, a current is applied to the second coil C2′ to apply a magnetic field in the y-axis direction to the magnetic core 110.

Namely, in the orthogonal fluxgate sensor according to the fourth exemplary embodiment of the present disclosure, the direction (here, the x-axis direction) of the external magnetic field intended to be measured and the direction (here, the y-axis direction) of the magnetic field generated by the magnetic field generating coil (here, the second coil C2′) to magnetize the magnetic core 110 form a right angle.

The current applied to the second coil C2′ is an AC, so the direction of the magnetic field thereof is repeatedly changing between a positive (+) direction and a negative (−) direction of the y axis.

When an instantaneous current value of the AC applied to the second coil C2′ is 0, the magnetic moment of the magnetic core 110 is maintained at the original value (with its component only along x-axis).

When the instantaneous current value of the AC applied to the second coil C2′ has a maximum positive value, the magnetic moment of the magnetic core 110 is saturated to the y-axis direction, and thus, the original component along the x-axis is rapidly reduced.

Here, the component along the x-axis of the magnetic moment of the magnetic core 110 is changed, and a change in magnetic flux corresponding thereto may be sensed by the first coil C1′.

Each time the instantaneous current value of the AC current applied to the second coil C2′ is changing between 0 and the maximum value thereof, the magnetic moment of the magnetic core 110 in the x-axis direction is changed and may be measured by the voltage induced to the first coil C1′.

The measured voltage of the first coil C1′ is proportional to a magnitude of the external magnetic field in the x-axis direction.

Namely, the external magnetic field in the x-axis direction may be detected by measuring the voltage induced to the first coil C1′.

Here, the second coil C2′ to which the AC power source is connected may serve as a magnetic field generating coil, and the first coil C1′ connected to the AC voltmeter may serve as a detecting coil.

Hereinafter, a method of measuring an external magnetic field (geo-magnetic field) in the y-axis direction will be described.

When an external magnetic field in the y-axis direction is applied, the magnetic core 110 has magnetic moment proportional to the external magnetic field in the y-axis direction.

Here, a current is applied to the first coil C1′ to apply a magnetic field in the x-axis direction to the magnetic core 110.

Namely, in the orthogonal fluxgate sensor according to the fourth exemplary embodiment of the present disclosure, the direction (here, the y-axis direction) of the external magnetic field intended to be measured and the direction (here, the x-axis direction) of the magnetic field generated by the magnetic field generating coil (here, the first coil C1′) to magnetize the magnetic core 110 form a right angle.

The current applied to the first coil C1′ is an AC, so the direction of the magnetic field thereof is repeatedly changing between a positive (+) direction and a negative (−) direction of the x axis.

When an instantaneous current value of the AC applied to the first coil C1′ is 0, the magnetic moment of the magnetic core 110 is maintained at the original value (with its component only along y-axis).

When the instantaneous current value of the AC applied to the first coil C1′ has a maximum positive value, the magnetic moment of the magnetic core 110 is saturated in the x-axis direction, and thus, the original component along the y-axis is rapidly reduced.

Here, the component along the y-axis of the magnetic moment of the magnetic core 110 is changed, and a change in magnetic flux corresponding thereto may be sensed by the second coil C2′.

Each time the instantaneous current value of the AC applied to the first coil C1 is changing between 0 and the maximum value thereof, the magnetic moment of the magnetic core 110 in the y-axis direction is changed and may be measured by the voltage induced to the second coil C2′.

The measured voltage of the second coil C2′ is proportional to a magnitude of the external magnetic field in the y-axis direction.

Namely, the external magnetic field in the y-axis direction may be detected by measuring the voltage induced to the second coil C2′.

Here, the first coil C1′ to which the AC power source is connected may serve as a magnetic field generating coil, and the second coil C2′ connected to the AC voltmeter may serve as a detecting coil.

In the orthogonal fluxgate sensor according to the fourth exemplary embodiment of the present disclosure, since the first and second coils C1′ and C2′ alternately serve as a magnetic field generating coil and a detecting coil, eliminating the need for a separate magnetic field generating coil and a detecting coil, the overall volume of the sensor may be reduced.

As set forth above, the orthogonal fluxgate sensor according to exemplary embodiments of the present disclosure may utilize a magnetic core and two coil structures perpendicular to one another.

Also, the orthogonal fluxgate sensor according to exemplary embodiments of the present disclosure may be formed by applying the magnetic core and the two coil structures perpendicular to one another to a printed circuit board (PCB) or a semiconductor wafer.

Also, since two coils alternately serve as a magnetic field generating coil and a detecting coil, the orthogonal fluxgate sensor may have a simpler structure and be miniaturized.

While exemplary embodiments have been shown and described above, it will be apparent to those skilled in the art that modifications and variations could be made without departing from the spirit and scope of the present disclosure as defined by the appended claims.

What is claimed is:

1. An orthogonal fluxgate sensor, comprising:
a magnetic core having a flat plate shape; and
first and second coils enclosing the magnetic core in a solenoid form,
wherein the first and second coils are disposed to be orthogonal to one another, and when an alternating current (AC) power source is connected to the first coil, an AC voltmeter is connected to the second coil, and when the AC power source is connected to the second coil, the AC voltmeter is connected to the first coil.

2. The orthogonal fluxgate sensor of claim 1, wherein a planar shape of the magnetic core is any one of square, rectangular, circular, and oval shapes.

3. The orthogonal fluxgate sensor of claim 1, wherein the magnetic core has lower demagnetizing field over a magnetic field whose direction is parallel to the plane thereof than those over a magnetic field whose direction is perpendicular to the plane thereof.

4. An orthogonal fluxgate sensor, comprising:
a magnetic core having a flat plate shape;
a first coil disposed above the magnetic core and having a spiral shape with the parts of the first coil directly above the magnetic core forming parallel lines; and
a second coil disposed below the magnetic core and having a spiral shape to repeatedly intersect the magnetic core in a perpendicular manner,
wherein the first and second coils are disposed to be orthogonal to one another, and when alternating current (AC) power is applied to the first coil, an AC voltmeter is connected to the second coil, and when AC power is applied to the second coil, the AC voltmeter is connected to the first coil.

5. The orthogonal fluxgate sensor of claim 4, wherein a planar shape of the magnetic core is any one of square, rectangular, circular, and oval shapes.

6. The orthogonal fluxgate sensor of claim 4, wherein the magnetic core has lower demagnetization characteristics over a magnetic field whose direction is parallel to the plane thereof than those over a magnetic field whose direction is perpendicular to the plane thereof.

7. The orthogonal fluxgate sensor of claim 4, wherein the magnetic core is positioned within a region of the first coil in which the current flows in one direction and within a region of the second coil in which the current flows in another direction.

8. An orthogonal fluxgate sensor, comprising:
a first substrate having a magnetic core formed therein;
second and third substrates stacked above and below the first substrate and having a first coil formed to enclose the magnetic core in a solenoid form; and
fourth and fifth substrates stacked above the second substrate and below the third substrate and having a second coil enclosing the magnetic core in a solenoid form,
wherein the first and second coils are disposed to be orthogonal to one another, and when an alternating current (AC) power source is connected to the first coil, an AC voltmeter is connected to the second coil, and when the AC power source is connected to the second coil, the AC voltmeter is connected to the first coil.

9. The orthogonal fluxgate sensor of claim 8, wherein the magnetic core has a flat plate shape.

10. The orthogonal fluxgate sensor of claim 8, wherein the magnetic core has lower demagnetizing field over a magnetic field whose direction is parallel to the plane thereof than those over a magnetic field whose direction is perpendicular to the plane thereof.

11. The orthogonal fluxgate sensor of claim 8, wherein a planar shape of the magnetic core is any one of square, rectangular, circular, and oval shapes.

12. The orthogonal fluxgate sensor of claim 8, wherein the second and third substrates have conductive patterns formed therein, and the first through third substrates have first via holes to allow end portions of the respective conductive patterns to be connected therethrough to form the first coil in a solenoid form.

13. The orthogonal fluxgate sensor of claim 8, wherein the fourth and fifth substrates have conductive patterns formed therein, and the first through fifth substrates have second via holes to allow end portions of the respective conductive patterns to be connected therethrough to form the second coil in a solenoid form.

14. The orthogonal fluxgate sensor of claim 8, wherein the fourth or fifth substrate has an electrode pattern to apply a current to the first or second coil.

15. An orthogonal fluxgate sensor, comprising:
a first substrate having a magnetic core formed therein;
a second substrate staked above the first substrate and having a first coil patterned to have a spiral shape such that the parts of the first coil directly above the magnetic core form parallel lines; and
a third substrate stacked below the first substrate and having a second coil patterned to have a spiral shape such that the parts of the second coil directly below the magnetic core form parallel lines,
wherein the first and second coils are patterned in the second and third substrates such that they are perpendicular to one another, and when an alternating current (AC) power source is connected to the first coil, an AC voltmeter is connected to the second coil, and when the AC power source is connected to the second coil, the AC voltmeter is connected to the first coil.

16. The orthogonal fluxgate sensor of claim 15, wherein the magnetic core has a flat plate shape.

17. The orthogonal fluxgate sensor of claim 15, wherein the magnetic core has lower demagnetizing field over a magnetic field whose direction is parallel to the plane thereof than those over a magnetic field whose direction is perpendicular to the plane thereof.

18. The orthogonal fluxgate sensor of claim 15, wherein a planar shape of the magnetic core is any one of square, rectangular, circular, and oval shapes.

19. The orthogonal fluxgate sensor of claim 15, wherein the magnetic core is positioned within a region of the first coil in which the current flows in one direction and within a region of the second coil in which the current flows in another direction.

20. The orthogonal fluxgate sensor of claim 15, wherein the magnetic core is positioned between start points and end points of the first and second coils patterned to have a spiral shape.
